(19) United States
(12) Patent Application Publication
(10) Pub. No.: US 2006/0043587 A1
(43) Pub. Date: Mar. 2, 2006

(54) Apparatus and method for reducing signal cross talk between wire bonds of semiconductor packages

(75) Inventors: Hong Tee Lim, San Jose, CA (US); Wee Keong Liew, San Jose, CA (US); Chengyu Guo, San Jose, CA (US)

Correspondence Address: LSI LOGIC CORPORATION, 1621 BARBER LANE, MS: D-106, MILPITAS, CA, 95035, US

(73) Assignee: LSI Logic Corporation, A Delaware Corporation, Milpitas, CA (US)

(21) Appl. No.: 10/931,682

(22) Filed: Aug. 31, 2004

(51) Int. Cl. H01L 23/48

(52) U.S. Cl. 257/738

(57) ABSTRACT

A semiconductor package for reducing signal cross talk between wire bonds of semiconductor packages by using a tier of input-output power bond pads between two tiers of signal bond pads. The package includes a substrate having a first surface and a second surface and a die attach area on the first surface of the substrate. A first tier of signal contacts is arranged around the periphery of the die attach on the first surface of the substrate. A second tier of signal contacts is arranged around the periphery of the die attach area on the first surface of the substrate. A power contact tier is also arranged around the periphery of the die attach area on the first surface of the substrate. The power contact tier is arranged between the first tier of signal contacts and the second tier of signal contacts to reduce signal noise and cross talk between the signal bond wires of the first tier and the second tier.

### BACKGROUND OF THE INVENTION

1. Field of the Invention

The present invention relates generally to semiconductor packaging, and more particularly, to an apparatus and method for reducing signal cross talk between bond wires of semiconductor packages by using a tier of power bond pads between two tiers of signal bond pads.

2. Description of the Related Art

Advances in processing technology have allowed engineers to fabricate more and more transistors on a semiconductor die of a given size. This increased circuit density has enabled circuit designers to add greater functionality with each new generation of chips. New functionality, however, increases the need for a greater number of signal inputs as well as power and ground inputs to the device. State of the art chip packages currently have hundreds and in some instances thousands of input-output pins. The increased number of input-output pins requires the bond pads and wire bonds to be spaced very close together on the die. The closeness of the wires may create a problem. Namely, coupling noise and cross talk between the wires may cause false signal transitions on the signal input-output pins, causing the device to fail.

One known high pin count packaging arrangement has a tiered bond pad arrangement of VSS, VDD2, VDDIO, SIGNAL and SIGNAL. With this arrangement, the power pads (VSS, VDD2 and VDDIO) are arranged in the inner three tiers while the outer two tiers are dedicated to signal pads. A number of solutions have been proposed to reduce the problem of coupling noise and cross talk with this type of arrangement. One conventional approach is to use wire bonds of different heights and loop profiles to reduce the cross talk and coupling noise between the wires. Another technique is to convert a significant number of signal bond pads into either ground (VSS) or power (VDD) pads. The spacing of either VSS or VDD pads between signal pads provides electrical shielding, isolating the adjacent signal and clock wires from coupling noise and cross talk. With one known package, the “shield to signal” ration is 4 to 1 (i.e., 4 signal pads to 1 VSS or VDD pad). The problem with this approach is that it reduces the total number of usable signal input-output pins on the package.

Accordingly, there is a need for an apparatus and method for reducing signal cross talk between wire bonds of semiconductor packages by using a tier of input-output power bond pads between two tiers of signal bond pads.

### SUMMARY OF THE INVENTION

The present invention relates to a semiconductor package for reducing signal cross talk between wire bonds of semiconductor packages by using a tier of input-output power bond pads between two tiers of signal bond pads. The package includes a substrate having a first surface and a second surface and a die attach area on the first surface of the substrate. A first tier of signal contacts is arranged around the periphery of the die attach on the first surface of the substrate. A second tier of signal contacts is arranged around the periphery of the die attach area on the first surface of the substrate. A power contact tier is also arranged around the periphery of the die attach area on the first surface of the substrate. The power contact tier is arranged between the first tier of signal contacts and the second tier of signal contacts to reduce signal noise and cross tall between the signal bond wires of the first tier and the second tier.

### BRIEF DESCRIPTION OF THE DRAWINGS

The invention, together with further advantages thereof, may best be understood by reference to the following description taken in conjunction with the accompanying drawings in which:

FIG. 1A is cross section of a semiconductor package of the present invention.

FIGS. 1B and 1C are top and bottom perspective views of the package of the present invention.

FIG. 2 is a flow diagram illustrating the steps of making the package of the present invention.

FIG. 3 is a top view of a substrate used in the package of the present invention.

FIG. 4 is a side view of wire bonds used in the package of the present invention according to one embodiment.

FIG. 5 is a side view of wire bonds used in the package of the present invention according to another embodiment.

In the figures, like reference numbers refer to like components and elements.

### DETAILED DESCRIPTION OF THE INVENTION

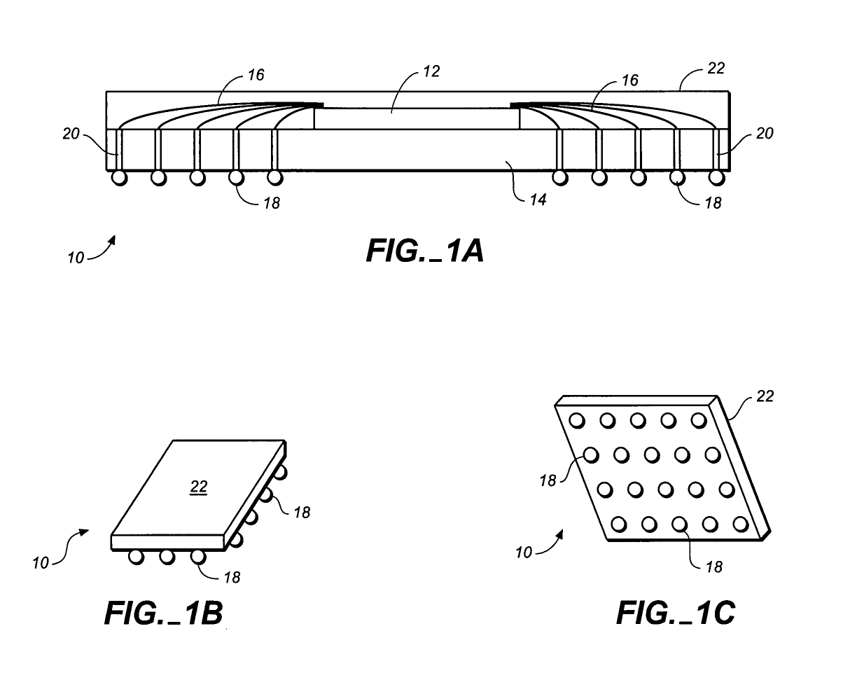

Referring to FIG. 1A, a cross section of a semiconductor package of the present invention is shown. The package 10 includes a semiconductor die 12 mounted onto the top or first surface of substrate 14. A plurality of bond wires 16 are provided to electrically couple bond pads (not visible) on the die 12 with contacts (not visible) on the first surface of the substrate 14. A plurality of contact balls 18 is provided on the second or bottom surface of the substrate 12. A plurality of vias 20 which are provided through the thickness of the substrate 14 are provided to electrically couple the contacts (again, not visible) on the first surface with the contact balls 18 on the second surface of the substrate 14 respectively. An encapsulant 22, such as an epoxy, is used to encapsulate the package 10.

Referring to FIG. 1B, a perspective view of the top of package 10 is shown. In this view, the encapsulant material 22 is visible on the top and side surfaces of the package 10. In FIG. 1C a perspective view of the bottom of the package is shown. In this view, the balls 18 are shown on the bottom surface of the package 10. The encapsulant 22 is visible on the side surfaces of the package. With both FIGS. 1B and 1C, the die 12, substrate 14, wire bonds 16 and vias 18 are embedded in the encapsulant 22, and therefore are not visible. The package 10 is sometimes referred to as a Ball Grid Array or “BGA” package because the contact balls 18 on the bottom of the package are arranged in an array.

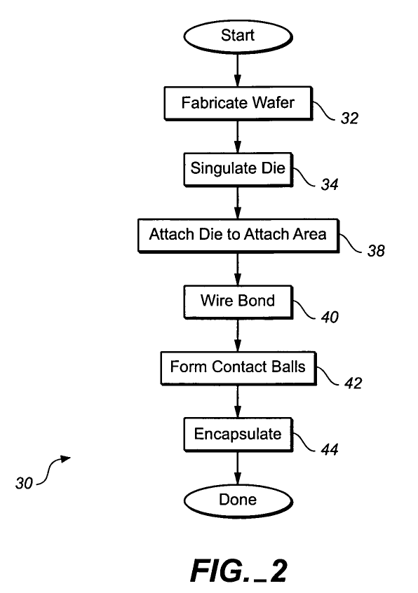

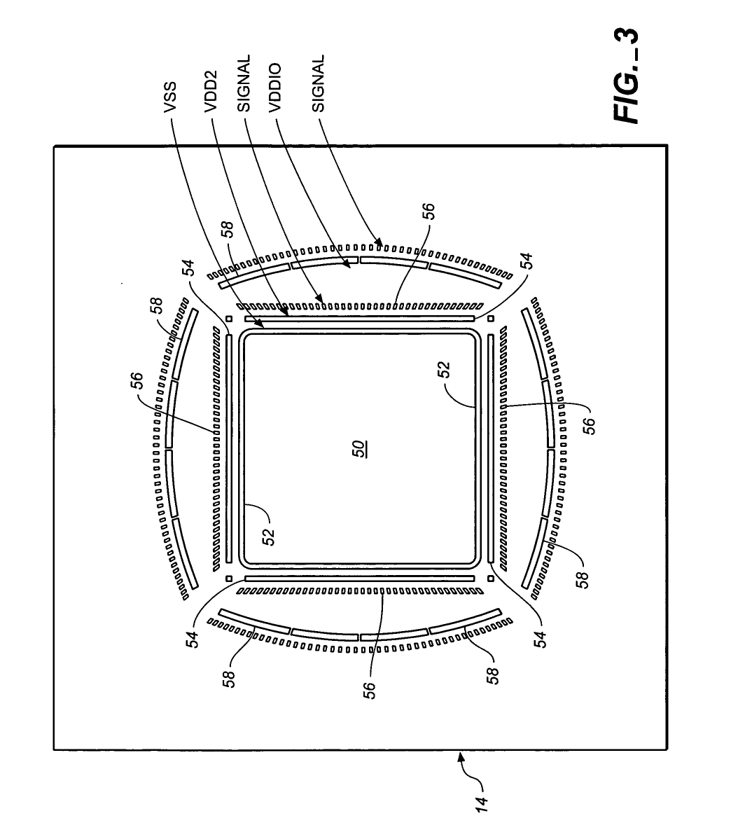

Referring to FIG. 2, a flow diagram 30 illustrating the steps of making the package of the present invention is shown. In the initial step, a wafer including a plurality of the semiconductor dice 12 is fabricated (box 32). The wafer is then scribed, singulating the individual die 12 from the wafer (box 34). Thereafter, a die 12 is attached to a die attach area on the substrate 14 using a die attach material such as epoxy or eutectic solder (box 38). Wire bonds 16 are formed between the bond pads on the die 12 and the contacts on the first surface of the substrate 14 (box 40). The contact balls 18 are then formed on the bottom surface of the substrate (box 42). In the final step, the package 10 is encapsulated (box 44).

Referring to FIG. 3, a top view of the substrate 14 used in the package 10 according to one embodiment of the present invention is shown. The top surface of the substrate 14 includes a die attach area 50 generally located in the center of the substrate. A plurality of tiers of contacts are arranged around the periphery of the die attach area on the top surface of the substrate 14. It should be noted that in the context of this application, the term “contact” should be broadly construed to mean either a ring, a segmented ring, pins, or any other shaped element used to provide an electrical contact for a bond wire. In the particular embodiment shown, the first or inner tier is a VSS contact ring 52. The second tier is a segmented ring of VDD2 contacts 54. The third tier is a ring of signal pins 56. The fourth tier is a segmented ring of VDDIO contacts 58. Finally, the fifth tier is a second plurality of signal pins 60 arranged in a ring. Thus in this embodiment, there are five tiers of contacts (VSS, VDD2, SIGNAL, VDDIO and SIGNAL). After a die 12 is attached to the die attach area 50, wire bonds 16 (not shown in FIG. 3) are formed between the contact pads on the die and the appropriate tiered contacts on the substrate 14. Note, VDD2 refers the power contacts used for the core logic on the die 12 and VDDIO refers to the power contacts used for input-output.

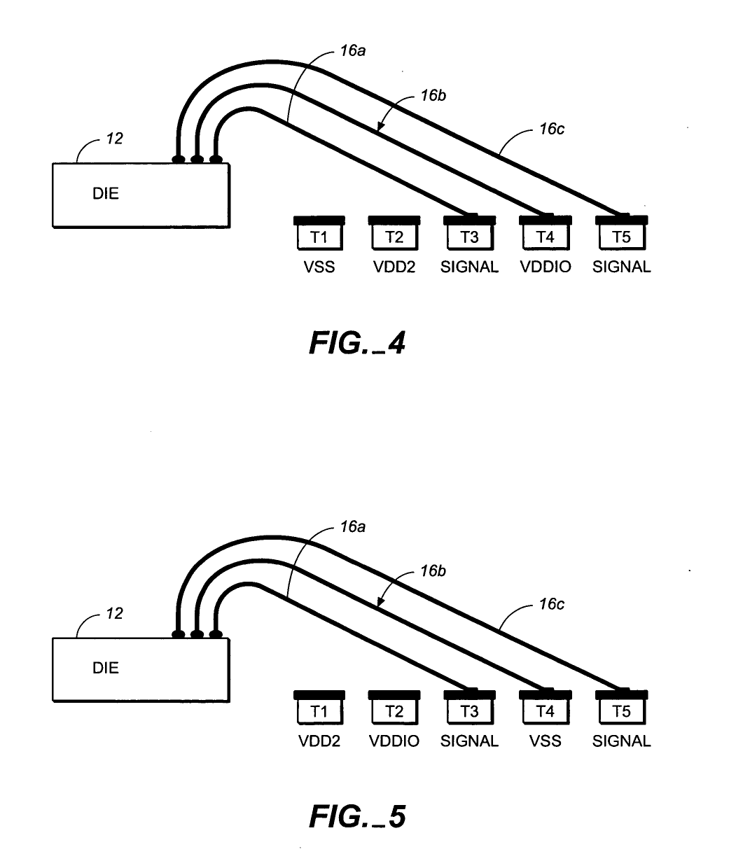

Referring to FIG. 4, a wire diagram of the package 10 is shown. In this diagram, the five tiers T1 through T5 of contacts are VSS, VDD2, SIGNAL, VDDIO and SIGNAL respectively. Wire bonds 16a, 16b and 16c are electrically coupled between bond pads on the die 12 and a SIGNAL contact (T3), a VDDIO contact (T4), and a SIGNAL contact (T5) respectively. The VDDIO bond wire 16b is positioned between the two SIGNAL bond wires 16a and 16c, thereby electrically isolating the two SIGNAL wires from one another. The VDDIO bond wire 16b thus minimizes cross talk and coupling noise between the SIGNAL wires 16c of tier T5 as well as between the bond wires 16a and 16c of tiers T3 and T5. In addition, the VDDIO wires 16b provide good return paths to the input/output signals of both tiers T3 and T5, thus reducing signal inductance.

Referring to FIG. 5 a wire diagram of the package 10 according to another embodiment is shown. In this diagram, the five tiers T1 through T5 of contacts are VDD2, VDDIO, SIGNAL, VSS and SIGNAL respectively. Wire bonds 16a, 16b and 16c are electrically coupled between bond pads on the die 12 and a SIGNAL contact (T3), a VSS contact (T4), and a SIGNAL contact (T5) respectively. The VSS bond wire 16b is positioned between the two SIGNAL bond wires 16a and 16c, thereby electrically isolating the two SIGNAL wires 16a and 16c. The VDDIO bond wire 16b thus minimizes cross talk and coupling noise between the SIGNAL wires 16c of tier T5 as well as the bond wires 16a and 16c of tiers T3 and T5. In addition, the VDDIO wires 16b provide good return paths to the input/output signals of both tiers T3 and T5, thus reducing signal inductance.

The present invention provides a number of benefits. It minimizes bond wire cross talk between high speed signals without wasting input-output pins and slots on the die. It also reduces signal inductance on the bond wires by providing improved return paths. Both of these advantages are realized using existing package manufacturing technology and with minimal modifications to substrate layout.

Although the foregoing invention has been described in some detail for purposes of clarity of understanding, it will be apparent that certain changes and modifications may be practiced within the scope of the appended claims. For example, the substrate 14 and described herein can be made of a number of different materials, such as ceramic or plastic. The substrate 14 also need not be a simple single layer substrate, but can be used with multiple layer substrates (e.g., 2, 3, 4, 5, 6 or more layers). Substrate 14 can also be a lead frame made of a metal such as copper or aluminum. Therefore, the described embodiments should be taken as illustrative and not restrictive, and the invention should not be limited to the details given herein but should be defined by the following claims and their full scope of equivalents.

We claim:

1. An apparatus, comprising;
a substrate having a first side and a second side;
a die attach area on the first side of the substrate;
a first tier of signal contacts arranged around the periphery of the die attach on the first side of the substrate;
a second tier of signal contacts arranged around the periphery of the die attach area on the first side of the substrate; and
a power contact tier arranged around the periphery of the die attach area on the first side of the substrate, the tier of power contact tier being arranged between the first tier of signal contacts and the second tier of signal contacts.

2. The apparatus of claim 1, wherein the power contact tier is a VDD tier.

3. The apparatus of claim 1, wherein the power contact tier is a VSS tier.

4. The apparatus of claim 1, further comprising a die attached to the die attach area.

5. The apparatus of claim 2, further comprising wire bonds electrically coupling bond pads on the die to the first, second and third tiers of contacts on the substrate.

6. The apparatus of claim 4, further comprising an encapsulant encapsulating the die and the substrate.

7. The apparatus of claim 1, wherein the first tier and the second tier of signal contacts are pins.

8. The apparatus of claim 1, wherein the power contact tier is a ring formed around the die attach area of the substrate.

9. The apparatus of claim 8, wherein the ring is segmented.

10. The apparatus of claim 1, wherein the power contact tier comprises a plurality of contacts arranged in a ring around the die attach area of the substrate.

11. The apparatus of claim 1, further comprising a plurality of contact balls arranged on the second side of the substrate, the plurality of contact balls electrically coupled to the first and second tier of signal contacts and the power contact tier through vias formed through the substrate respectively.

12. A method, comprising:
placing a semiconductor die onto a die attach area on a substrate, the substrate having a plurality of tiered contacts arranged adjacent the die attach area; and
forming a first wire bond between the die and a first tier contact, the first tier contact configured as a signal contact;
forming a second wire bond between the die and a second tier contact, the second tier contact configured as a power contact; and
forming a third wire bond between the die and a third tier contact, the third tier contact configured as a signal contact, whereby the second wire bond provides an electrical isolation effect to reduce cross talk and noise between the first wire bond and the third wire bond.

13. The method of claim 12, wherein the second tier contact is VSS.

14. The method of claim 12, wherein the second tier contact is VDD.
